(19) United States
(12) Patent Application Publication
(10) Pub. No.: US 2023/0071933 A1
(43) Pub. Date: Mar. 9, 2023

(54) PLANAR MULTI-LAYER RADIO FREQUENCY FILTERS INCLUDING STACKED COILS WITH STRUCTURAL CAPACITANCE

(71) Applicant: LAM RESEARCH CORPORATION, Fremont, CA (US)

(72) Inventors: Sunil KAPOOR, Vancouver, WA (US); Eric MADSEN, Sherwood, OR (US); Dan MAROHL, San Jose, CA (US)

(21) Appl. No.: 17/800,168

(22) PCT Filed: Feb. 16, 2021
(86) PCT No.: PCT/US2021/018153

§ 371 Date: Aug. 16, 2022

Related U.S. Application Data
(60) Provisional application No. 62/979,770, filed on Feb. 21, 2020.

(51) Int. Cl. H01J 37/32

(52) U.S. Cl. CPC H01J 37/32174; H01J 37/32091; H01J 37/32724; H01J 2237/332

(57) ABSTRACT

A radio frequency filter is provided and includes a dielectric layer and a first inductor. The first inductor includes an input, a first coil disposed on a first side of the dielectric layer and connected to the input, and a second coil disposed on a second side of the dielectric layer opposite the first side. The first and second coils are planar, such that windings of the first coil are in a first layer and windings of the second coil are in a second layer. The first coil overlaps and is connected in series with the second coil. The first coil, the dielectric layer and the second coil collectively provide a capacitance of the radio frequency filter. The first inductor further includes a first via extending through the dielectric layer and connected to the first coil and the second coil and a first output connected to the second coil.

### CROSS-REFERENCE TO RELATED APPLICATIONS

This application claims the benefit of U.S. Provisional Application No. 62/979,770, filed on Feb. 21, 2020. The entire disclosure of the application referenced above is incorporated herein by reference.

### FIELD

The present disclosure relates to tank circuits and filtering substrate support heating elements.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate support (e.g., a pedestal or electrostatic chuck) includes a body. Electrostatic clamping and radio frequency (RF) electrodes and one or more heater elements are disposed in the body. Power is supplied to the heater elements through a filter box, which is external to the substrate support. The filter box includes RF filters that are connected by cables to leads in a support column of the substrate support. The leads are connected to the heating elements.

The RF filters in the filter box are utilized to prevent RF leaking from the RF electrodes through the heating elements to ground. RF leaking can occur due to the heating elements being in close proximity to the RF electrodes and RF coupling between the heating elements and the RF electrodes.

### SUMMARY

A radio frequency filter is provided and includes a dielectric layer and a first inductor. The first inductor includes a first input, a first coil disposed on a first side of the dielectric layer and connected to the first input, and a second coil disposed on a second side of the dielectric layer opposite the first side. The first coil and the second coil are planar, such that windings of the first coil are in a first layer and windings of the second coil are in a second layer. The first coil overlaps and is connected in series with the second coil. The first coil, the dielectric layer and the second coil collectively provide a capacitance of the radio frequency filter. The first inductor further includes a first via extending through the dielectric layer and connected to the first coil and the second coil and a first output connected to the second coil.

In other features, the capacitance of the radio frequency filter is equal to a product of (i) a dielectric constant of the dielectric layer and (ii) an area of overlap between the first coil and the second coil divided by a thickness of the dielectric layer. In other features, the first coil and the second coil are wound in a same direction. In other features, the input is disposed across from and on an opposite end of the radio frequency filter than the output. In other features, the input is disposed adjacent to and on a same end of the radio frequency filter as the output.

In other features, the radio frequency filter further includes: a first capacitance patch connected to of the first coil; and a second capacitance patch connected to of the second coil, where the second capacitance patch is disposed opposite the first capacitance patch to increase capacitance between the first coil and the second coil.

In other features, a substrate processing system is provided and includes: a substrate support comprising a heating element; the radio frequency filter disposed outside the substrate support and connected to one of an input or an output of the substrate support by a first conductive element; and a second radio frequency filter disposed outside the substrate support and connected to the other one of the input or the output of the substrate support by a second conductive element.

In other features, the dielectric layer of the radio frequency filter describe above and is a portion of a support layer; and an inductor of the second radio frequency filter is implemented on the dielectric layer. In other features, the dielectric layer of the radio frequency filter described above is a portion of a first support layer; and an inductor of the second radio frequency filter is implemented on a second support layer different than the first substrate. In other features, the second radio frequency filter includes: a third coil wound adjacent the first coil and disposed on the first side of the dielectric layer; and a fourth coil wound adjacent the second coil and disposed on the second side of the dielectric layer.

In other features, a substrate processing system is provided and includes a substrate support and a power source. The substrate support includes a heating element, the radio frequency filter connected to one of an input or an output of the heating element, wherein the dielectric layer is a layer of the substrate support, and a second radio frequency filter connected to the other one of the input or the output of the heating element. The power source supplies power to the input of the heating element through one of the radio frequency filter or the second radio frequency filter.

In other features, a radio frequency filter assembly is provided and includes: the radio frequency filter and a second radio frequency filter. The second radio frequency filter includes a second inductor including a second input, a third coil disposed on the first side of the dielectric layer and connected to the second input, and a fourth coil disposed of the second side of the dielectric layer opposite the first side. The third coil and the fourth coil are planar, such that windings of the third coil are in the first layer and windings of the fourth coil are in the second layer. The third coil overlaps and is connected in series with the fourth coil. The third coil, the dielectric layer and the fourth coil collectively provide a second capacitance of the radio frequency filter. The second radio frequency filter further includes: a first via extending through the dielectric layer and connected to the first coil and the second coil; a second via extending through the dielectric layer and connected to the third coil and the fourth coil; and a second output connected to the second coil.

In other features, the third coils and the fourth coil are wound in a same direction as the first coil and the second coil. In other features, the first input is adjacent to the second input and the first output is adjacent to the second output. In other features, the first input and the second input are adjacent to and on same ends of the radio frequency filter assembly as the first output and the second output.

In other features, the radio frequency filter further includes: a first capacitance patch connected to and increasing capacitance of the first coil or the third coil; and a second capacitance patch connected to and increasing capacitance of the second coil or the fourth coil. In some embodiments, the second capacitance patch is disposed opposite the first capacitance patch.

In other features, a substrate processing system is provided and includes: a substrate support comprising a heating element; and the radio frequency filter assembly disposed outside the substrate support and connected to an input and an output of the substrate support by conductive elements. In other features, the dielectric layer is at least a portion of a support layer disposed outside of the substrate support.

In other features, a substrate processing system is provided and includes a substrate support and a power source. The substrate support includes a heating element and the radio frequency filter assembly, which is connected to an input and an output of the heating element. The dielectric layer is a layer of the substrate support. The power source supplies power to the input of the heating element through one of the first radio frequency filter or the second radio frequency filter.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a perspective view of an example of an inductor of a multi-layer RF filter including singular wound coils with an input disposed across from an output in accordance with an example of the present disclosure;

FIG. 2 is a top view of the inductor of FIG. 1;

FIG. 3 is a perspective view of an example of inductors of a RF filter assembly including a multi-layer RF filters including pairs of dual wound coils with inputs disposed across from outputs in accordance with an example of the present disclosure;

FIG. 4 is a top view of the inductors of FIG. 3;

FIG. 5 is a cross-sectional side view of an example of a substrate support and filter box including multi-layer RF filters with singular wound coils with inputs disposed across from outputs in accordance with an example of the present disclosure;

FIG. 6 is a cross-sectional side view of an example of a substrate support and filter box including multi-layer RF filters with singular wound coils with inputs disposed proximate to outputs in accordance with an example of the present disclosure;

FIG. 7 is a cross-sectional side view of an example of a substrate support and filter box including multi-layer RF filters with pairs of dual wound coils with inputs disposed proximate to outputs in accordance with an example of the present disclosure;

FIG. 8 is a functional block diagram of an example substrate processing system including a substrate support including multi-layer radio frequency (RF) filters with singular wound coils and inputs disposed proximate to outputs in accordance with an example of the present disclosure;

FIG. 9 is a cross-sectional side view of an example of a substrate support including multi-layer RF filters with singular wound coils with inputs disposed adjacent outputs in accordance with an example of the present disclosure;

FIG. 10 is a cross-sectional side view of an example of a substrate support including multi-layer RF filters with singular wound coils with inputs disposed across from outputs in accordance with an example of the present disclosure;

FIG. 11 is a cross-sectional side view of an example of a substrate support including multi-layer RF filters with pairs of dual wound coils with inputs disposed across from outputs in accordance with an example of the present disclosure;

FIG. 12 is a cross-sectional side view of an example of a substrate support including stacked multi-layer RF filters with singular wound coils with inputs disposed across from outputs in accordance with an example of the present disclosure;

FIG. 13 is a top view of an example of an inductor of a multi-layer RF filter including singular wound coils and capacitance patches in accordance with an example of the present disclosure; and

FIG. 14 is a top view of an example of inductors of multi-layer RF filters including pairs of dual wound coils and capacitance patches in accordance with an example of the present disclosure.

In the drawings, reference numbers may be reused to identify similar and/or identical elements.

### DETAILED DESCRIPTION

RF filters aid in improving operating efficiency of a RF system by filtering out RF signals having certain frequencies and reducing noise. RF filters are used in both deposition and etching tools of substrate processing systems. RF filters are used to filter out and prevent radio frequencies from being received at certain devices, which can degrade if RF signals are received. As an example, RF filters are used on input and output lines of pedestal heating elements to prevent RF frequencies from being passed from the heating elements to power sources of the pedestal heating elements.

Power may be fed to heating elements in a pedestal by a RF filter box. The RF filter box is connected to a pedestal and includes multiple RF filters with discrete RF filter components. The RF filters typically include inductors and capacitors with a large envelope. The inductors are wire-wound inductors for which it is difficult to maintain a predetermined pitch between and diameter of windings during manufacturing. The RF filters are bulky and prone to variability and failure over time. The discrete components are mounted on a printed circuit board (PCB) or directly mounted in the filter box using fixtures, straps and wires for connections. Manual assembly of the filter boxes is a large source of error which results in variability and non-reliability. Manual mounting of inductors is the largest source of variability. Also, due to the large size of the discrete components being in a confined space, voltage arcing and component breakdown can occur. The RF filter components in the RF filter box are too large and are not configured and/or formed of materials suitable to be integrated into a pedestal.

RF filter boxes are typically installed under a pedestal and connected to the pedestal by cables. Space available under a pedestal is typically limited. This poses installation and maintenance issues. Also, the RF filter box can be a primary source of RF radiation. This is due to RF coupling between RF electrodes and heating elements in the pedestal. RF energy can be transferred from the RF electrodes to the heating elements, which is then transferred to the RF filter box. In addition, RF radiation variability is high in the RF filter box due to proximity between components and flexible cables used to connect the RF filter box to the pedestal. The RF variability is associated with different amounts of power being coupled between RF electrodes and heating elements, which changes RF radiation. The RF variability is also associated with changes in positions of parts (e.g., cables), which changes capacitances and as a result changes RF radiation. Additional RF variability can exist due to differences in manufacturing of RF components.

The examples set forth herein include planar multi-layer RF filters that are compact, thin, accurate, robust, repeatable and reliable. The multi-layer RF filters are band reject filters configured to attenuate and thus reject particular radio frequencies and/or radio frequencies within predetermined ranges. The multi-layer RF filters provide greater than 30 dB attenuation and provide high input impedance (e.g., greater than 2 kilo-ohms (kΩ)). The high input impedance prevents radio frequencies passing from, for example, a heating element in a substrate support to a power source and/or ground. The multi-layer RF filters do not include discrete components and may be fabricated using an automated manufacturing process (e.g., additive manufacturing processes). No manual assembly is required and/or involved in manufacturing the RF filters. As a result, high manufacturing accuracy is provided and can be easily maintained during manufacturing of multiple RF filters. The stated manufacturing is highly accurate, repeatable, and reliable.

The RF filters disclosed herein may be formed on a support layer, such as a substrate of a PCB for installation in a filter box. As an alternative, the RF filters may be integrally formed within a substrate support of a substrate processing system. Using, for example, a ceramic support layer can provide more than an 80% area reduction and substantially reduce RF losses as compared to traditional RF filters. Lengths and widths of the disclosed RF filters can be 70% smaller than lengths and widths of traditional RF filters. Heights of the disclosed RF filters may be 90% smaller than heights of traditional RF filters. These size reductions can double the operating efficiency of a RF system. A reduction in RF filter size, increases distances from surrounding components increases breakdown voltages needed to degrade the RF filters and surrounding components, which minimizes potential failures of the RF filters and surrounding components and allows for higher voltages and/or power levels to be used. The disclosed RF filters also cost less than the stated traditional RF filters.

Example substrate supports with integrated RF filters are provided. The RF filters may be sized and formed of materials suitable for being implemented within a substrate support and filtering high frequency coupling from current passing through heating elements. An RF filter may be integrated into the substrate supports for each input and output leg of each heating element. As a result, each of the heating elements has multiple RF filters. This prevents RF leaking to ground and/or to a power source. The substrate supports may be fabricated to include the RF filters.

By integrating the RF filters into the substrate supports, RF filters for heating elements are not needed in RF filter boxes external to the substrate supports. This frees up space external to and/or underneath the substrate supports for other purposes. In some example embodiments, an RF filter box is not used and power is supplied directly to the substrate supports. No additional high RF filtering is needed external to the substrate supports. This eliminates the RF coupling to ground and/or a power source through the RF filter box and RF radiation variability associated with a RF filter box. In some embodiments, the integrated filters include printed components having tight tolerances, which further minimize RF radiation variability.

An inductor typically has stray capacitance between windings of the inductor. This stray capacitance causes the inductor to resonate at a frequency, which depends on the stray capacitance. When designing a tank circuit including the inductor, the tank circuit may be designed, such that the resonance frequency is far away from an operating frequency to prevent interference. The example tank circuits (or RF filters) disclosed herein are structured such that the stray capacitances are used as at least a portion of the capacitances of the tank circuits.

The tank circuits include inductors that each are divided into two stacked coiled halves, where each of the halves are disposed in different layers and separated by a dielectric material. The halves of each coil are connected in series. The inductor may be divided into two equally sized halves having conductive elements with equal length. A first half may overlap and be aligned in two directions (e.g., X and Y directions) with the second half. The second half may be at least partially a mirror image of the first half. Capacitance is provided between first windings of the first half and second windings of the second half. An area of overlap and distance between the halves (or thickness of the dielectric material) and a corresponding dielectric constant are predetermined and controlled to provide a predetermined capacitance and resonance frequency for the corresponding tank circuit. The coiled halves are wound in a same direction, such that current flow in the coils is in a same direction. This ensures addition of flux and hence inductance. The inductance and capacitance of the tank circuit (or RF filter) are provided in a parallel configuration.

Resonator structure capacitance is provided by overlapping areas of conductive elements of the coils and may be defined by equation 1, where C is capacitance, ε is the dielectric constant of the dielectric (or substrate) material, A is the total overlapping area of the conductive elements of the halves, and d is the thickness of the dielectric material (or distance between the halves). The areas, sizes, materials, distances between the coils, and amount of overlap of the coils may be adjusted to adjust the capacitance of the corresponding RF filter. The capacitance is provided without inclusion of a discrete capacitor. Resonance of the tank circuit may be defined by equation 2, where Fᵣₑₛ is the resonance frequency and L is inductance of the tank circuit.

$$C = \frac{ε A}{d} \qquad ( 1 )$$

$${F}_{res} = \frac{1}{2 π \sqrt{L C}} \qquad ( 2 )$$

Single layer inductance may be calculated using as described in the paper titled “Simple Accurate Expressions for Planar Spiral Inductances” by Sunderarajan S. Mohan, et al. in IEEE Journal of Solid-State Circuits, Vol. 34 No. 10, October 1999. For the RF filters disclosed herein, total inductance is double that for a single coil because each inductor includes two coils.

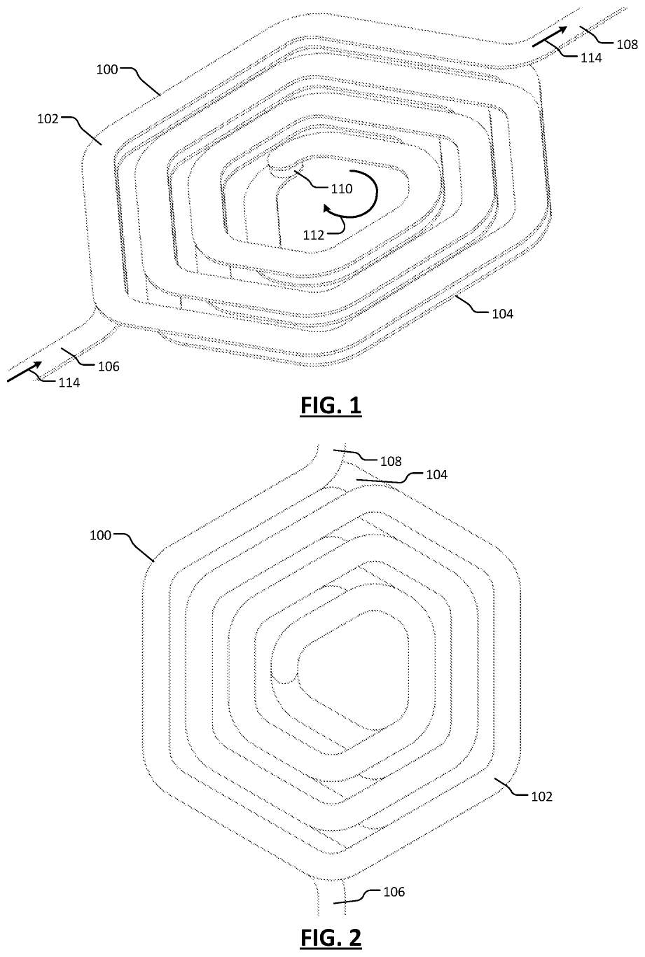

FIGS. 1-2 show an inductor 100 of a multi-layer RF filter including singular wound coils 102, 104 with an input leg 106 and an output leg 108. The input leg 106 is disposed across from and on an opposite end of the multi-layer RF filter than the output leg 108. The coils 102, 104 and dielectric material between the coils 102, 104 provide a capacitor. Dielectric material is disposed between the coils 102, 104 and between windings of each of the coils 102, 104. The coils 102, 104 are connected near a center of the coils 102, 104 by a via 110. As used herein, the term “via” refers to an electrical connection extending between layers. The first coil 102 is disposed above and overlaps the second coil 104.

The amount of overlap is maximized, such that: a minimal portion of the first coil 102 does not overlap a corresponding portion of the second coil 104 when viewed in a first direction; and a minimal portion of the second coil 104 is not overlapped by a corresponding portion of the first coil 102 when viewed in a second direction opposite the first direction. The first coil 102 is wound in a same direction (clockwise or counterclockwise) from an input to an output of the first coil 102 as the second coil 104, as represented by the arrow 112. Arrows 114 show an example of direction of current flow, where the input is on the bottom layer and the output is on the top layer. In one embodiment, the RF filter 100 is connected differently such that current is flowing through the RF filter in an opposite direction, where the input is on the top layer and the output is on the bottom layer.

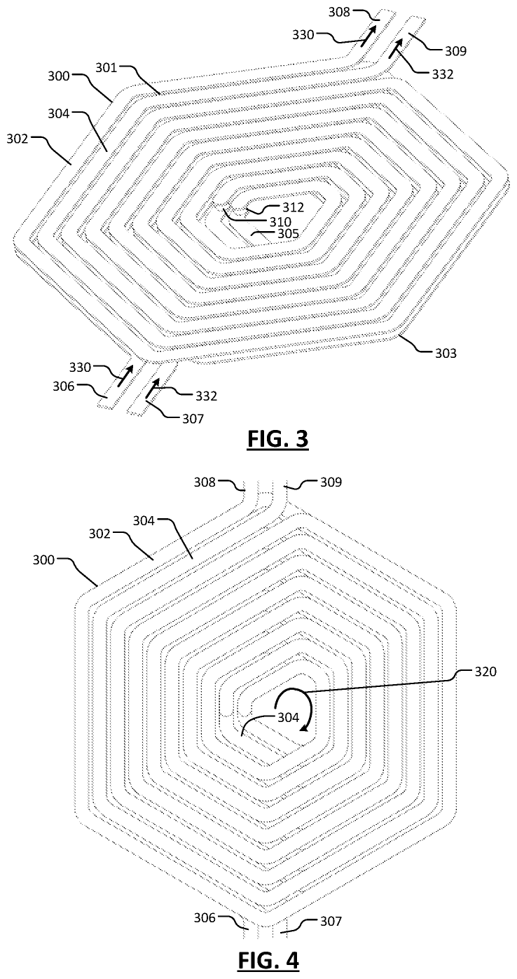

FIGS. 3-4 show inductors 300, 301 of multi-layer RF filters having dual wound coils 302, 303, 304, 305 with inputs 306, 307 disposed across from outputs 308, 309. The coils 302, 303 and 304, 305 and dielectric material between the coils 302, 303 and 304, 305 provide capacitors. Dielectric material is disposed between the coils 302, 303, 304, 305 and between windings of each of the coils 302, 303, 304, 305. The multi-layer RF filter includes two tank circuits; one provided by coils 302, 303 and another provided by coils 304, 305. The coils 302, 304 are connected to coils 303, 305 near centers of the coils 302, 303, 304, 305 by vias 310, 312. The first coil 302 is disposed above and overlaps the second coil 303. The third coil 304 is disposed above and overlaps the fourth coil 305.

The amount of overlap is maximized, such that: a minimal portion of the first coil 302 does not overlap a corresponding portion of the second coil 303 when viewed in a first direction; a minimal portion of the second coil 303 is not overlapped by a corresponding portion of the first coil 302 when viewed in a second direction opposite the first direction; a minimal portion of the third coil 304 does not overlap a corresponding portion of the fourth coil 305 when viewed in the first direction; and a minimal portion of the fourth coil 305 is not overlapped by a corresponding portion of the third coil 304 when viewed in the second direction. The coils 302-305 are wound in a same direction (clockwise or counterclockwise), as represented by the arrow 320. Arrows 330, 332 show examples of the directions of current flow, where both inputs are on the bottom layer and both outputs are on the top layer. In one embodiment, the RF filter 300 is connected differently such that current is flowing through the RF filter in opposite directions, where both inputs are on the top layer and both outputs are on the bottom layer.

Although FIGS. 3-4 shown pairs of coils wound in a parallel arrangement where each pair of coils is in a corresponding layer, each layer may have any number of coils wound in parallel. For example, a similar arrangement may be provided by winding three conductive elements in parallel, where each layer of coils includes three coils. The conductive elements referred to herein may each include a conductive trace, filament, wire, etc. that may be formed from an electrically conductive material (e.g., a metallic material).

The inputs and outputs of the coils of FIGS. 1-4 may be adjacent to each other, across from each other and/or in other locations. This holds true for other coils disclosed herein. The coils 102, 104, 302, 304 of FIGS. 1-4 and other coils disclosed herein are shown having particular shapes, the coils disclosed herein may have various other shapes. The coils may be, for example, square shaped, spiral shaped, or take on other arbitrary shapes. Each of the coils may have any number of windings.

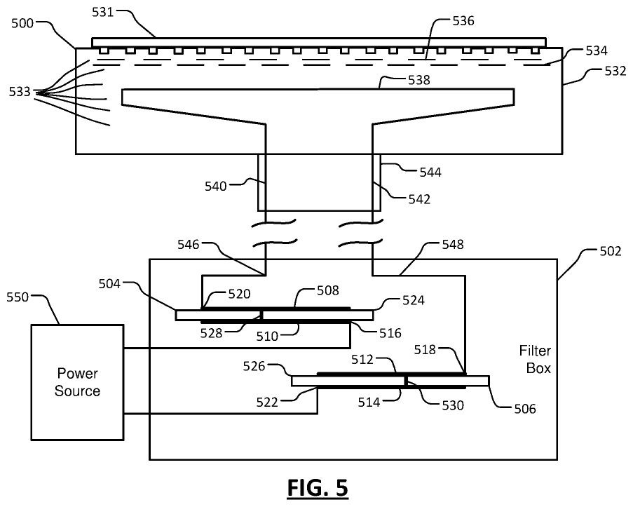

FIG. 5 shows a substrate support 500 and filter box 502 including multi-layer RF filters 504, 506. The RF filters 504, 506 include inductors with singular wound coils 508, 510, 512, 514 with inputs 516, 518 across from outputs 520, 522. In some embodiments, the coils 508, 510, 512, 514 are configured similarly as the coils 102, 104 of FIG. 1. The coils 508, 510 have a first capacitance and the coils 512, 514 have a second capacitance. The coils 508, 510, 512, 514 are disposed on support layers (e.g., PCBs) 524, 526 and are connected by vias 528, 530. The support layers may be dielectric layers including vias. Although shown on separate distinct support layers, the coils 508, 510, 512, 514 may be implemented on a same support layer. The RF filters 504, 506 may replace and/or be replaced by other RF filters disclosed herein.

The substrate support 500 supports a substrate 531 and includes a body 532 having multiple layers, some of which are identified with numerical designator 533. The layers 533 include electrodes 534, 536, and a heating element 538. The heating elements referred to herein may each include an electrically resistive conductor configured to radiate thermal energy. The electrically resistive conductor converts electrical energy into heat and has a resistance that when encountered by electrical current results in heating of the electrically resistive conductor. As a couple of examples, the electrically resistive conductor may be formed of a metallic material and/or intermetallic material. Dielectric material is disposed between the electrodes 534, 536 and the heating element 538. The heating element 538 is implemented in a single layer and may have any winding pattern.

Each of the RF filters 504, 506 are planar filters that each include a single inductor provided by the coils 508, 510, 512, 514 and the vias 528, 530. Each of the inductors is disposed in multiple layers and includes conductive elements that may wind in various patterns. The conductive elements of each of the inductors are connected at first ends to the vias 528, 530. Each second end of the conductive elements performs as one of the inputs 516, 518 or outputs 520, 522.

The heating element 538 is connected to the output 520 of the first RF filter 504 and the input 518 of the second RF filter 506 by conductive elements 540, 542, which extend in a support column 544, and conductive elements 546, 548 in the filter box 502. During operation, power is received at the first RF filter 504 from a power source 550 and provided to the heating element 538. Power returns from the heating element 538 to the power source 550 through the second RF filter 506.

The dielectric layers among multiple layers 533 of the substrate support 500 may be formed of one or more ceramic compositions and may include, for example, aluminum nitride (AlN₃), aluminum oxide (Al₂O₃), and/or aluminum oxynitride (AlON). The coils 508, 510, 512, 514 of the inductors, the vias 528, 530 and the conductive elements 540, 542, 546, 548 may be formed of one or more nickel alloys, one or more platinum alloys, one or more rhodium alloys, one or more iridium alloys, one or more gold nickel alloys, one or more copper nickel alloys, one or more copper tungsten alloys and/or one or more palladium alloys.

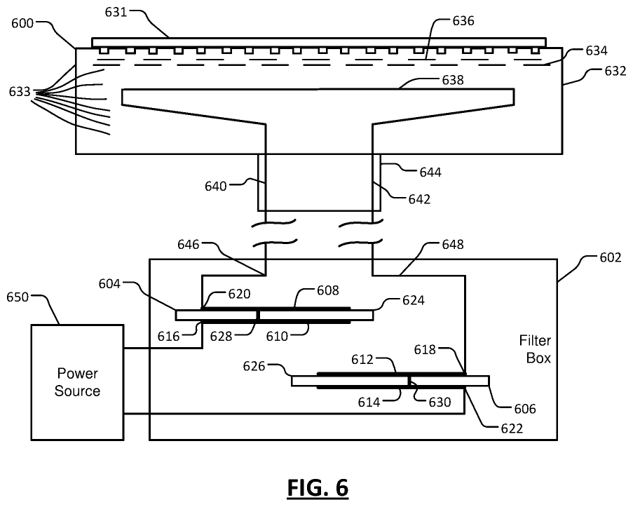

FIG. 6 shows a substrate support 600 and filter box 602 including multi-layer RF filters 604, 606. The RF filters 604, 606 include inductors with singular wound coils 608, 610, 612, 614 with inputs 616, 618 proximate to outputs 620, 622. In some embodiments, the coils 608, 610, 612, 614 are configured similarly as the coils 102, 104 of FIG. 1, except the inputs are disposed across from the outputs. The coils 608, 610 have a first capacitance and the coils 612, 614 have a second capacitance. The coils 608, 610, 612, 614 are disposed on support layers (e.g., PCBs) 624, 626 and are connected by vias 628, 630, respectively. The support layers may be dielectric layers including vias. Although shown on separate distinct support layers, the coils 608, 610, 612, 614 may be implemented on a same support layer. The RF filters 604, 606 may replace and/or be replaced by other RF filters disclosed herein.

The substrate support 600 supports a substrate 631 and includes a body 632 having multiple layers, some of which are identified with numerical designator 633. The layers 633 include electrodes 634, 636, and a heating element 638. Dielectric material is disposed between the electrodes 634, 636 and the heating element 638. The heating element 638 is implemented in a single layer and may have any winding pattern.

Each of the RF filters 604, 606 are planar filters that each include a single inductor provided by the coils 608, 610, 612, 614 and the vias 628, 630. Each of the inductors is disposed in multiple layers and includes conductive elements that may wind in various patterns. The conductive elements of each of the inductors are connected at first ends to the vias 628, 630. Each second end of the conductive elements performs as one of the inputs 616, 618 or outputs 620, 622.

The heating element 638 is connected to the output 620 of the first RF filter 604 and the input 618 of the second RF filter 606 by conductive elements 640, 642, which extend in a support column 644, and conductive elements 646, 648 in the filter box 602. During operation, power is received at the first RF filter 604 from a power source 650 and provided to the heating element 638. Power returns from the heating element 638 to the power source 650 through the second RF filter 606.

The dielectric layers among the multiple layers 633 of the substrate support 600 may be formed of one or more ceramic compositions and may include, for example, aluminum nitride (AlN₃), aluminum oxide (Al₂O₃), and/or aluminum oxynitride (AlON). The coils 608, 610, 612, 614 of the inductors, the vias 628, 630 and the conductive elements 640, 642, 646, 648 may be formed of one or more nickel alloys, one or more platinum alloys, one or more rhodium alloys, one or more iridium alloys, one or more gold nickel alloys, one or more copper nickel alloys, one or more copper tungsten alloys and/or one or more palladium alloys.

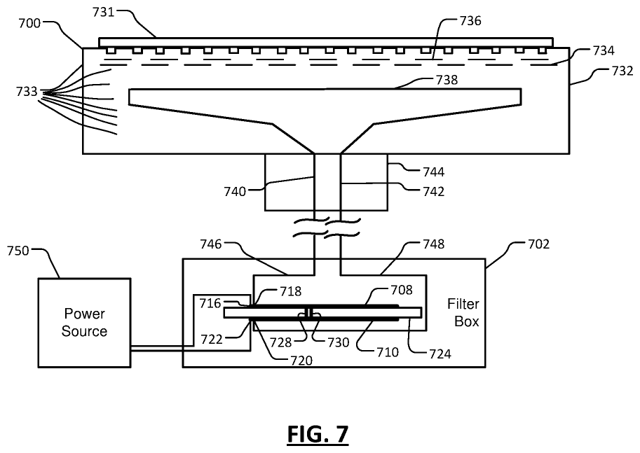

FIG. 7 shows a substrate support 700 and filter box 702 including multi-layer RF filters with pairs of dual wound coils (top pair of coils 708 and bottom pair of coils 710) with inputs 716, 718 proximate to outputs 720, 722. In one embodiment, each RF filter includes one of the coils 708 and one of the coils 710. In some embodiments, the coils 708, 710 are configured similarly as the coils 302-305 of FIG. 3, except the inputs are disposed on opposing sides of a support layer (e.g., PCB) 724 across from the outputs. In the example shown the one of the inputs is vertically above one of the outputs and another one of the inputs is vertically below another one of the outputs. The coils 708, 710 may be replaced with the coils 302-305. The coils 708, 710 have respective capacitances. The coils 708, 710 are disposed on the support layer 724 and are connected by vias 728, 730. The support layer 724 may be a dielectric layer including vias. Each of the coils 708 is connected to a respective one of the coils 710 by one of the vias 728, 730. The RF filters may replace and/or be replaced by other RF filters disclosed herein.

The substrate support 700 supports a substrate 731 and includes a body 732 having multiple layers, some of which are identified with numerical designator 733. The layers 733 include electrodes 734, 736, and a heating element 738. Dielectric material is disposed between the electrodes 734, 736 and the heating element 738. The heating element 738 is implemented in a single layer and may have any winding pattern.

Each of the RF filters are planar filters that each include a single inductor provided by the coils 708, 710 and the vias 728, 730. Each of the inductors is disposed in multiple layers and includes conductive elements that may wind in various patterns. For example, a first inductor may include one of the coils 708 that is in a first conductive layer and one of the coils 710 that is in a second conductive layer, where the support layer 724 is disposed between the first conductive layer and the second conductive layer. A second inductor may include another one of the coils 708 that is disposed in the first conductive layer and another one of the coils 710, which is disposed in the second conductive layer. The conductive elements of each of the inductors are connected at first ends to the vias 728, 730. Each second end of the conductive elements performs as one of the inputs 716, 718 or outputs 720, 722.

The heating element 738 is connected to the output 720 of the first RF filter and the input 718 of the second RF filter by conductive elements 740, 742, which extend in a support column 744, and conductive elements 746, 748 in the filter box 702. During operation, power is received at the first RF filter from a power source 750 and provided to the heating element 738. Power returns from the heating element 738 to the power source 750 through the second RF filter.

The dielectric layers 733 of the substrate support 700 may be formed of one or more ceramic compositions and may include, for example, aluminum nitride (AlN₃), aluminum oxide (Al₂O₃), and/or aluminum oxynitride (AlON). The coils 708, 710 of the inductors, the vias 728, 730 and the conductive elements 740, 742, 746, 7648 may be formed of one or more nickel alloys, one or more platinum alloys, one or more rhodium alloys, one or more iridium alloys, one or more gold nickel alloys, one or more copper nickel alloys, one or more copper tungsten alloys and/or one or more palladium alloys.

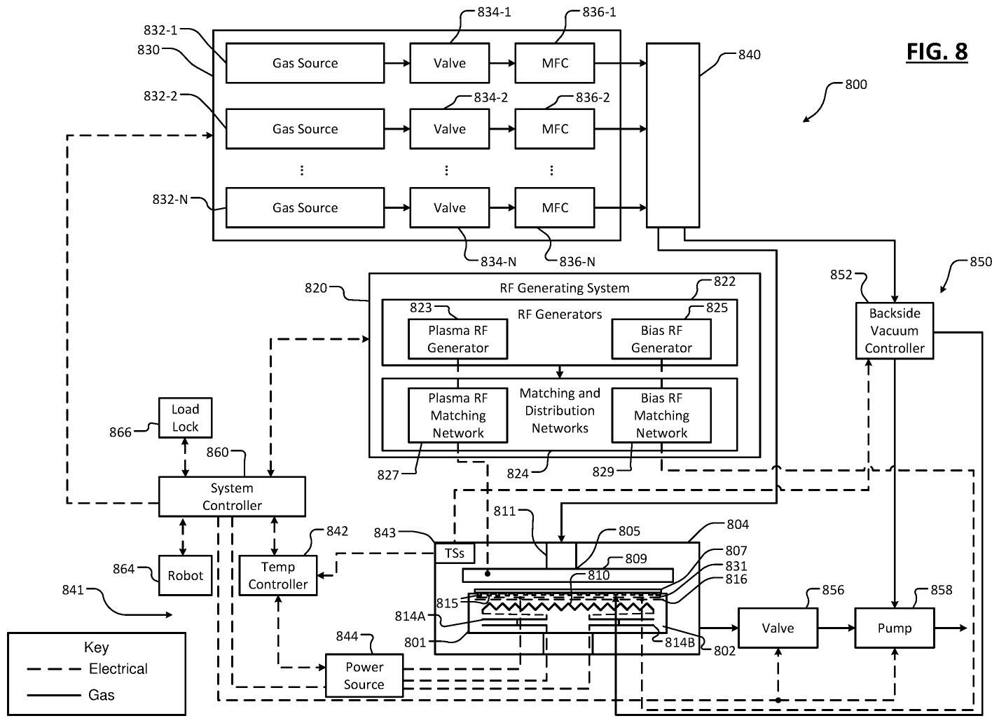

FIG. 8 shows an example substrate processing system 800 including a substrate support 801, shown as an electrostatic chuck. The substrate support 801 may be configured the same or similarly as any of the substrate supports disclosed herein including that shown in FIGS. 5-7, 9-12. Although FIG. 8 shows a capacitive coupled plasma (CCP) system, the embodiments disclosed herein are applicable to transformer coupled plasma (TCP) systems, inductively coupled plasma (ICP) systems and/or other systems and plasma sources that include a substrate support. The embodiments are applicable to plasma enhanced chemical vapor deposition (PECVD) processes, chemically enhanced plasma vapor deposition (CEPVD) processes, atomic layer deposition (ALD) processes, and/or other processes in which substrate temperatures are greater than or equal to 450° C. In the example shown, the substrate support 801 includes a monolithic anisotropic body 802. The body 802 may be formed of different materials and/or different ceramic compositions. The body 802 may include, for example, aluminum nitride (AlN₃), aluminum oxide (Al₂O₃), and/or aluminum oxynitride (AlON).

The substrate processing system 800 includes a processing chamber 804. The substrate support 801 is enclosed within the processing chamber 804. The processing chamber 804 also encloses other components, such as an upper electrode 805, and contains RF plasma. During operation, a substrate 807 is arranged on and electrostatically clamped to the substrate support 801. For example only, the upper electrode 805 may include a showerhead 809 that introduces and distributes gases. The showerhead 809 may include a stem portion 811 including one end connected to a top surface of the processing chamber 804. The showerhead 809 is generally cylindrical and extends radially outward from an opposite end of the stem portion 811 at a location that is spaced from the top surface of the processing chamber 804. A substrate-facing surface of the showerhead 809 includes holes through which process or purge gas flows. Alternately, the upper electrode 805 may include a conducting plate and the gases may be introduced in another manner.

The substrate support 801 may include temperature control elements (TCEs) also referred to as heating elements. As an example, FIG. 8 shows the substrate support 801 including a heating element 810. The heating element 810 receives power and heats the substrate support 801. The substrate support 801 also includes multi-layer RF filters 814 (identified as 814A and 814B) with singular wound coils and inputs proximate to outputs. The RF filters 814 are connected to the inlet and outlet legs of the heating element 810. Other integrated heating element and RF filter examples are described with respect to FIGS. 1-7 and 9-14. In an embodiment, the substrate support 801 includes one or more gas channels 815 for flowing backside gas to a backside of the substrate 807.

An RF generating system 820 generates and outputs RF voltages to the upper electrode 805 and one or more lower electrodes 816 in the substrate support 801. One of the upper electrode 805 and the substrate support 801 may be DC grounded, AC grounded or at a floating potential. For example only, the RF generating system 820 may include one or more RF generators 822 (e.g., a capacitive coupled plasma RF power generator, a bias RF power generator, and/or other RF power generator) that generate RF voltages, which are fed by one or more matching and distribution networks 824 to the upper electrode 805 and/or the substrate support 801. An electrode that receives an RF signal, an RF voltage and/or RF power is referred to as a RF electrode. As an example, a plasma RF generator 823, a bias RF generator 825, a plasma RF matching network 827 and a bias RF matching network 829 are shown. The plasma RF generator 823 may be a high-power RF generator producing, for example, 6-10 kilo-watts (kW) of power or more. The bias RF matching network supplies power to RF electrodes, such as RF electrodes 816.

A gas delivery system 830 includes one or more gas sources 832-1, 832-2, . . . , and 832-N (collectively gas sources 832), where N is an integer greater than zero. The gas sources 832 supply one or more precursors and gas mixtures thereof. The gas sources 832 may also supply etch gas, carrier gas and/or purge gas. Vaporized precursor may also be used. The gas sources 832 are connected by valves 834-1, 834-2, . . . , and 834-N (collectively valves 834) and mass flow controllers 836-1, 836-2, . . . , and 836-N (collectively mass flow controllers 836) to a manifold 840. An output of the manifold 840 is fed to the processing chamber 804. For example only, the output of the manifold 840 is fed to the showerhead 809.

The substrate processing system 800 further includes a heating system 841 that includes a temperature controller 842, which may be connected to the heating element 810. The temperature controller 842 controls a power source 844, which supplies power to the heating element 810 using one of the RF filters 814. Although shown separately from a system controller 860, the temperature controller 842 may be implemented as part of the system controller 860. The substrate support 801 may include multiple temperature controlled zones, where each of the zones includes temperature sensors and heating elements. The temperature controller 842 may monitor temperatures as indicated by the temperature sensors and adjust current, voltage and/or power to the heating elements to adjust the temperatures to target temperatures. The power source 844 may also provide power, including a high voltage, to clamping electrodes 831 to electrostatically clamp the substrate 807 to the substrate support 801. Clamping electrodes receive power to electrostatically clamp down the substrate 807 to the substrate support 801 and may receive RF signals, RF voltages and/or RF power. The power source 844 may be controlled by the system controller 860.

The substrate processing system 800 further includes a cooling system 850 that includes a backside vacuum controller 852. The backside vacuum controller 852 may receive gas from the manifold 840 and supply the gas to the channels 815 and/or to a pump 858. This improves transfer of thermal energy between the substrate support 801 and the substrate 807. The backside gas may also be provided to improve substrate peripheral edge purging and vacuum tracking of a location of the substrate 807. The channels 815 may be fed by one or more injection ports. In one embodiment, multiple injection ports are included for improved cooling. As an example, the backside gas may include helium.

The temperature controller 842 may control operation and thus temperatures of heating elements and, as a result, temperatures of a substrate (e.g., the substrate 807). The temperature controller 842 controls current supplied to the heating elements based on detected parameters from temperature sensors 843 within the processing chamber 804. The backside vacuum controller 852 controls flow rate of backside gas (e.g., helium) to the gas channels 815 for cooling the substrate 807 by controlling flow from one or more of the gas sources 832 to the gas channels 815. The backside vacuum controller 852 controls pressure and flow rates of gas supplied to channels 815 based on detected parameters from the temperature sensors 843. In one embodiment, the temperature controller 842 and the backside vacuum controller 852 are implemented as a combined single controller.

The temperature sensors 843 may include resistive temperature devices, thermocouples, digital temperature sensors, and/or other suitable temperature sensors. During a deposition process, the substrate 807 may be heated in presence of high-power plasma. Flow of gas through the channels 815 may reduce temperatures of the substrate 807.

A valve 856 and the pump 858 may be used to evacuate reactants from the processing chamber 804. The system controller 860 may control components of the substrate processing system 800 including controlling supplied RF power levels, pressures and flow rates of supplied gases, RF matching, etc. The system controller 860 controls states of the valve 856 and the pump 858. A robot 864 may be used to deliver substrates onto, and remove substrates from, the substrate support 801. For example, the robot 864 may transfer substrates between the substrate support 801 and a load lock 866. The robot 864 may be controlled by the system controller 860. The system controller 860 may control operation of the load lock 866.

The valves, gas pumps, power sources, RF generators, etc. referred to herein may be referred to as actuators. The heating elements, gas channels, etc. referred to herein may be referred to as temperature adjusting elements.

The substrate support 801 may be a stratified and/or lamellar structure that includes a monolithic body 802. As an example, the substrate support 801 includes multiple layers including dielectric layers, heating element layers, intermediate layers with vias, inductor layers, capacitor layers, etc. Makeup and materials of the layers are further described below.

In the example shown, the electrodes 816, 831 are disposed in an uppermost one of the layers. The heating element 810 is disposed in another one of the layers. Although a single heating element 810 is shown, any number of heating elements may be included in the substrate support 801. The heating elements may have different sizes, shapes and provide corresponding heating patterns and be allocated to respective heating zones of the substrate support 801. A dielectric layer is disposed between the electrodes 816, 831 and the heating element 810. The RF filters 814 are disposed in additional layers below the heating element layer.

Although the substrate supports of FIGS. 5-12 are each shown as having certain features and not other features, each of the substrate supports may be modified to include any of the features disclosed herein and in FIGS. 5-12. The heating elements of the substrate supports may correspond to respective heating zones of the substrate supports. Each of the heating elements may include a respective pair of RF filters, as disclosed herein.

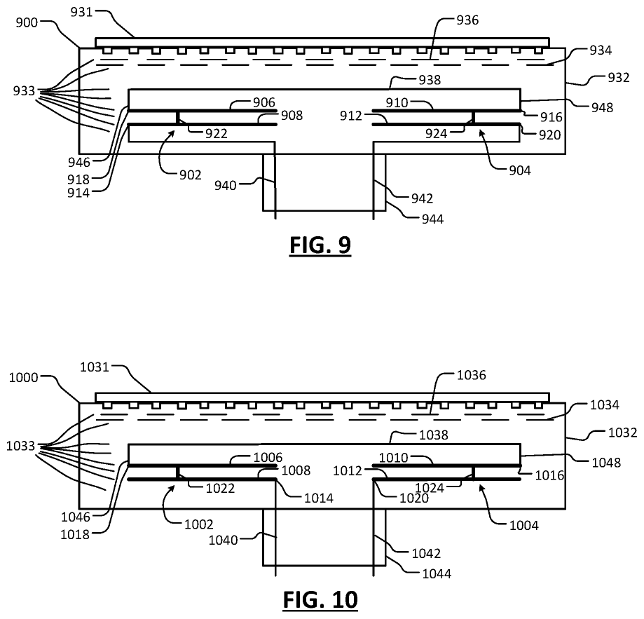

FIG. 9 shows a substrate support 900 including multi-layer RF filters 902, 904 with singular wound coils 906, 908, 910, 912 with inputs 914, 916 adjacent outputs 918, 920. The coils 906, 908 and the coils 910, 912 are connected by vias 922, 924. The RF filters 902, 904 may be configured as other RF filters disclosed herein. In some embodiments, the coils 906, 908, 910, 912 may be similar to the coils shown in FIG. 1, except that the inputs 914, 916 are adjacent the outputs 918, 920.

The substrate support 900 supports a substrate 931 and includes a body 932 having multiple layers, some of which are identified with numerical designator 933. The layers 933 include electrodes 934, 936, and a heating element 938. Dielectric material is disposed between the electrodes 934, 936 and the heating element 938. The heating element 938 is implemented in a single layer and may have any winding pattern.

Conductive elements 940, 942 extend through a support column 944 and connect to the input 914 and the output 920. Conductive elements 946, 948 connect the output 918 and the input 916 to the heating element 938.

FIG. 10 shows a substrate support 1000 including multi-layer RF filters 1002, 1004 with singular wound coils 1006, 1008, 1010, 1012 with inputs 1014, 1016 across from outputs 1018, 1020. The coils 1006, 1008 and the coils 1010, 1012 are connected by vias 1022, 1024. The RF filters 1002, 1004 may be configured as other RF filters disclosed herein. In some embodiments, the coils 1006, 1008, 1010, 1012 may be similar to the coils shown in FIG. 1.

The substrate support 1000 supports a substrate 1031 and includes a body 1032 having multiple layers, some of which are identified with numerical designator 1033. The layers 1033 include electrodes 1034, 1036, and a heating element 1038. Dielectric material is disposed between the electrodes 1034, 1036 and the heating element 1038. The heating element 1038 is implemented in a single layer and may have any winding pattern.

Conductive elements 1040, 1042 extend through a support column 1044 and connect to the input 1014 and the output 1020. Conductive elements 1046, 1048 connect the output 1018 and the input 1016 to the heating element 1038.

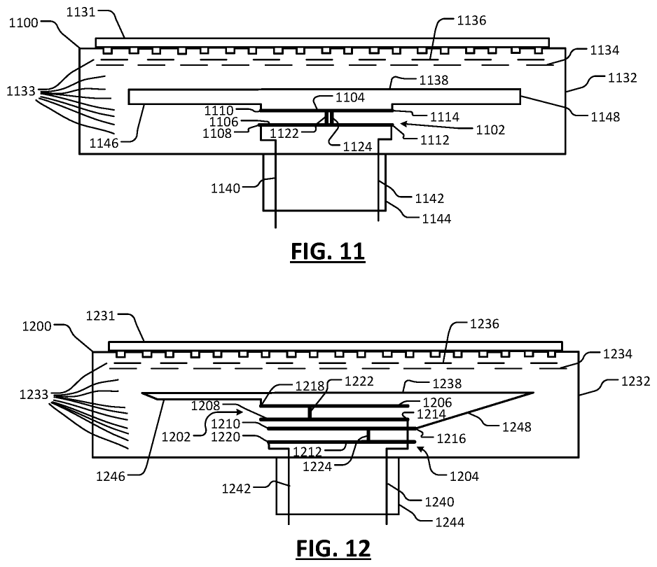

FIG. 11 shows a substrate support 1100 including multi-layer RF filters 1102 with pairs of dual wound coils 1104, 1106 with inputs 1108, 1110 across from outputs 1012, 1014. The coils 1104, 1106 are connected by vias 1122, 1124. The RF filters 1102, 1104 may be configured as other RF filters disclosed herein. In some embodiments, the coils 1104, 1106 may be similar to the coils shown in FIG. 3.

The substrate support 1100 supports a substrate 1131 and includes a body 1132 having multiple layers, some of which are identified with numerical designator 1133. The layers 1133 include electrodes 1134, 1136, and a heating element 1138. Dielectric material is disposed between the electrodes 1134, 1136 and the heating element 1138. The heating element 1138 is implemented in a single layer and may have any winding pattern.

Conductive elements 1140, 1142 extend through a support column 1144 and connect to the input 1108 and the output 1112. Conductive elements 1146, 1148 connect the input 1110 and the output 1104 to the heating element 1138.

FIG. 12 shows a substrate support 1200 including stacked multi-layer RF filters 1202, 1204 with singular wound coils 1206, 1208, 1210, 1212 with inputs 1214, 1216 across from outputs 1218, 1220. The RF Filter 1202 is disposed at least partially above the RF filter 1204. The coils 1206, 1208 and the coils 1210, 1212 are connected by vias 1222, 1224. The RF filters 1202, 1204 may be configured as other RF filters disclosed herein. In some embodiments, the coils 1206, 1208, 1210, 1212 may be similar to the coils shown in FIG. 1.

The substrate support 1200 supports a substrate 1231 and includes a body 1232 having multiple layers, some of which are identified with numerical designator 1233. The layers 1233 include electrodes 1234, 1236, and a heating element 1238. Dielectric material is disposed between the electrodes 1234, 1236 and the heating element 1238. The heating element 1238 is implemented in a single layer and may have any winding pattern.

Conductive elements 1240, 1242 extend through a support column 1244 and connect to the input 1214 and the output 1220. Conductive elements 1246, 1248 connect the output 1218 and the input 1216 to the heating element 1238.

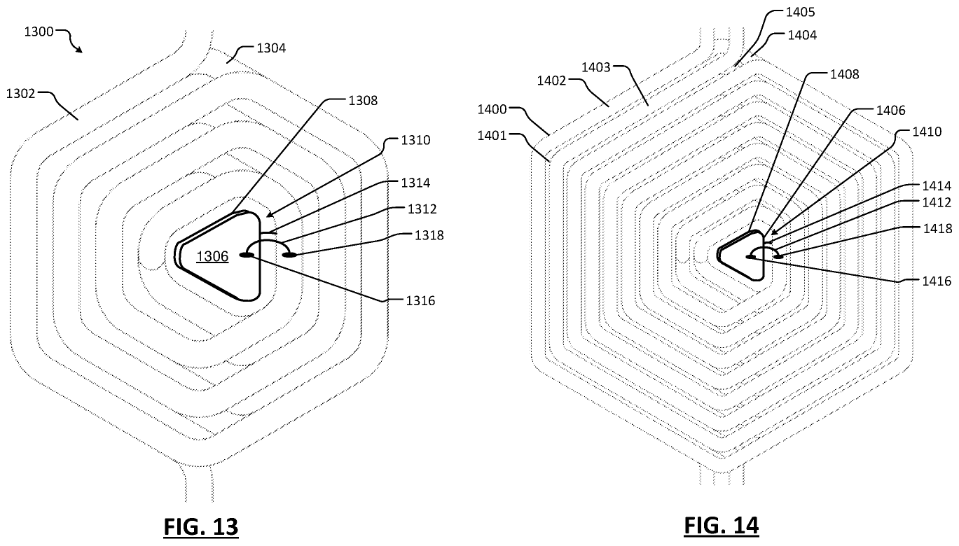

FIG. 13 shows an inductor 1300 of a multi-layer RF filter including singular wound coils 1302, 1304 including capacitance patches 1306, 1308. The capacitance patches 1306, 1308 are disposed within center openings 1310 of the coils 1302, 1304 and provide additional capacitance. The capacitance patch 1306 is disposed above and overlaps the capacitance patch 1308. The capacitance patches 1306, 1308 may be of various sizes and shapes and formed of may be formed of one or more nickel alloys, one or more platinum alloys, one or more rhodium alloys, one or more iridium alloys, one or more gold nickel alloys, one or more copper nickel alloys, one or more copper tungsten alloys and/or one or more palladium alloys. In one embodiment, the capacitance patches 1306, 1308 are the same size and shape.

Although shown in the center openings 1310 of the capacitances patches 1306, 1308 may be in other locations. In one embodiment, the capacitance patches 1306, 1308 are disposed outside a periphery of the coils 1302, 1304. The capacitances patches 1306, 1308 are connected to the coils 1302, 1304 by jumpers 1312, 1314. The jumpers 1312, 1314 may be attached by solder bumps (two solder bumps 1316, 1318 are shown).

In an embodiment, the capacitance patches 1306, 1308 are formed along with the coils 1302, 1304 and the jumpers 1312, 1314 are later added during a tuning process. Although one pair of capacitance patches are shown, any number of pairs of capacitance patches may be included and one or more of the pairs of capacitance patches may be connected by corresponding jumpers.

FIG. 14 shows inductors 1400, 1401 of multi-layer RF filters including dual wound coils 1402, 1403, 1404, 1405 including capacitance patches 1406, 1408. The capacitance patches 1406, 1408 are disposed within center openings 1410 of the coils 1402, 1403, 1404, 1405 and provide additional capacitance. The capacitance patches 1406 is disposed above and overlaps the capacitance patch 1408. The capacitance patches 1406, 1408 may be of various sizes and shapes and formed of may be formed of one or more nickel alloys, one or more platinum alloys, one or more rhodium alloys, one or more iridium alloys, one or more gold nickel alloys, one or more copper nickel alloys, one or more copper tungsten alloys and/or one or more palladium alloys. In one embodiment, the capacitance patches 1406, 1408 are the same size and shape.

Although shown in the center openings 1410 of the capacitances patches 1406, 1408 may be in other locations. In one embodiment, the capacitance patches 1406, 1408 are disposed outside a periphery of the coils 1402, 1404. The capacitances patches 1406, 1408 are connected to the coils 1402, 1404 by jumpers 1412, 1414. The jumpers 1412, 1414 may be attached by solder bumps (two solder bumps 1416, 1418 are shown). Although a single pair of capacitance patches are shown, multiple pairs of capacitance patches may be included. In one embodiment, a first pair of capacitance patches is provided for coils 1402, 1404 and a second pair of capacitance patches is provided for coils 1403, 1405.

In an embodiment, the capacitance patches 1406, 1408 are formed along with the coils 1402, 1403 and the jumpers 1412, 1414 are later added during a tuning process. Although one pair of capacitance patches are shown, any number of pairs of capacitance patches may be included and one or more of the pairs of capacitance patches may be connected by corresponding jumpers.

The capacitance patches 1306, 1308, 1306, 1408 of FIGS. 13-14 are used for tuning purposes. The capacitance patches 1306, 1308, 1306, 1408 are included to adjust capacitance of the corresponding RF filters and, as a result, resonance frequencies of the RF filters. As a few examples, the resonance frequencies may be 11.8 MHz, 13.6 MHz, 15 MHz, 22.8 MHz, 27.12 MHz, 40 MHz, 60 MHz or 100 MHZ. The capacitance patches 1306, 1308, 1306, 1408 may be provided to adjust RF frequencies filtered out by the RF filters.

The tank circuits (or RF filters) disclosed herein are easy to manufacture on PCBs. Thick or thin film technology may be used to, for example, form the RF filters on alumina or other low loss dielectric material. This provides increased repeatability, reduced losses, and improved accuracy. No surface mount and/or discrete capacitor is required. A source of variability of PCB based capacitors is the dielectric constant of the support layer (or PCB substrate fiberglass). Tightly controlled dielectrics, such as alumina, provide consistency and repeatability. One technique for providing consistency in capacitance is tuning the capacitance as described above with respect to FIGS. 13-14. Capacitance patches may be sized and located and attached to adjust capacitance of a RF filter to a predetermined capacitance. The RF filters herein include planar inductors for which it is easy to maintain pitch between and diameter of windings. The dimensions are able to be accurately controlled during manufacturing, which improves consistency and repeatability.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A radio frequency filter comprising:
a dielectric layer; and
a first inductor comprising
a first input,
a first coil disposed on a first side of the dielectric layer and connected to the first input,
a second coil disposed on a second side of the dielectric layer opposite the first side, wherein the first coil and the second coil are planar, such that windings of the first coil are in a first layer and windings of the second coil are in a second layer, wherein the first coil overlaps and is connected in series with the second coil, and wherein the first coil, the dielectric layer and the second coil collectively provide a capacitance of the radio frequency filter,
a first via extending through the dielectric layer and connected to the first coil and the second coil, and
a first output connected to the second coil.

2. The radio frequency filter of claim 1, wherein the capacitance of the radio frequency filter is equal to a product of (i) a dielectric constant of the dielectric layer and (ii) an area of overlap between the first coil and the second coil divided by a thickness of the dielectric layer.

3. The radio frequency filter of claim 1, wherein:
the first coil is wound in one of a clockwise direction or a counterclockwise direction from an input of the first coil to an output of the first coil; and
the second coil is wound in a same one of the clockwise direction or the counterclockwise direction, as the first coil, from an input of the second coil to an output of the second coil.

4. The radio frequency filter of claim 1, wherein the first input is disposed across from and on an opposite end of the radio frequency filter than the first output.

5. The radio frequency filter of claim 1, wherein the first input is disposed adjacent to and on a same end of the radio frequency filter as the first output.

6. The radio frequency filter of claim 1, further comprising:
a first capacitance patch connected to of the first coil; and
a second capacitance patch connected to of the second coil, wherein the second capacitance patch is disposed opposite the first capacitance patch to increase capacitance between the first coil and the second coil.

7. A substrate processing system comprising:
a substrate support comprising a heating element;
the radio frequency filter of claim 1 disposed outside the substrate support and connected to one of an input or an output of the substrate support by a first conductive element; and
a second radio frequency filter of claim 1 disposed outside the substrate support and connected to the other one of the input or the output of the substrate support by a second conductive element.

8. The substrate processing system of claim 7, wherein:
the dielectric layer of the radio frequency filter is a portion of a support layer; and
an inductor of the second radio frequency filter is implemented on the dielectric layer.

9. The substrate processing system of claim 7, wherein:
the dielectric layer of the radio frequency filter is a portion of a first support layer; and
an inductor of the second radio frequency filter is implemented on a second support layer different than the first support layer.

10. The substrate processing system of claim 7, wherein the second radio frequency filter comprises:
a third coil wound adjacent the first coil and disposed on the first side of the dielectric layer; and
a fourth coil wound adjacent the second coil and disposed on the second side of the dielectric layer.

11. A substrate processing system comprising:
a substrate support comprising
a heating element,
the radio frequency filter of claim 1 connected to one of an input or an output of the heating element, wherein the dielectric layer is a layer of the substrate support, and
a second radio frequency filter connected to the other one of the input or the output of the heating element; and
a power source supplying power to the input of the heating element through one of the radio frequency filter of claim 1 or the second radio frequency filter.

12. A radio frequency filter assembly comprising:
the radio frequency filter of claim 1; and
a second radio frequency filter comprising
a second inductor comprising
a second input,
a third coil disposed on the first side of the dielectric layer and connected to the second input,
a fourth coil disposed of the second side of the dielectric layer opposite the first side, wherein the third coil and the fourth coil are planar, such that windings of the third coil are in the first layer and windings of the fourth coil are in the second layer, wherein the third coil overlaps and is connected in series with the fourth coil, and wherein the third coil, the dielectric layer and the fourth coil collectively provide a second capacitance of the radio frequency filter,
a second via extending through the dielectric layer and connected to the third coil and the fourth coil, and
a second output connected to the fourth coil.

13. The radio frequency filter assembly of claim 12, wherein the third coils and the fourth coil are wound in a same direction as the first coil and the second coil.

14. The radio frequency filter assembly of claim 12, wherein:
the first input is adjacent to the second input; and
the first output is adjacent to the second output.

15. The radio frequency filter assembly of claim 12, wherein the first input and the second input are adjacent to and on same ends of the radio frequency filter assembly as the first output and the second output.

16. The radio frequency filter of claim 12, further comprising:
a first capacitance patch connected to and increasing capacitance of the first coil or the third coil; and
a second capacitance patch connected to and increasing capacitance of the second coil or the fourth coil, wherein the second capacitance patch is disposed opposite the first capacitance patch.

17. A substrate processing system comprising:
a substrate support comprising a heating element; and
the radio frequency filter assembly of claim 12 disposed outside the substrate support and connected to an input and an output of the substrate support by conductive elements.

18. The substrate processing system of claim 17, wherein the dielectric layer is at least a portion of a support layer disposed outside of the substrate support.

19. A substrate processing system comprising:
a substrate support comprising
a heating element, and
the radio frequency filter assembly of claim 12 connected to an input and an output of the heating element, wherein the dielectric layer is a layer of the substrate support; and
a power source supplying power to the input of the heating element through one of the radio frequency filter or the second radio frequency filter.

20. The radio frequency filter of claim 1, wherein the first via is the only via connecting the first coil to the second coil.

21. The radio frequency filter of claim 6, wherein:
the first capacitance patch is disposed in a center of the first coil; and
the second capacitance patch is disposed in a center of the second coil.

22. The radio frequency filter of claim 12, wherein:
the first coil extends parallel to the third coil; and
the second coil extends parallel to the fourth coil.

23. The radio frequency filter of claim 12, wherein:
the first coil is wound in a same plane as the third coil; and
the second coil is wound in a same plane as the fourth coil.

24. The radio frequency filter of claim 12, wherein:
each of the first coil and the third coil comprise a plurality of windings wound in a first plane;
each of the second coil and the fourth coil comprise a plurality of windings wound in a second plane; and
the second plane is parallel to the first plane.

25. The radio frequency filter of claim 12, wherein:
the first coil and the third coil wind in a same direction from inputs of the first coil and the third coil to outputs of the first coil and the third coil; and
the second coil and the fourth coil wind in a same direction from inputs of the second coil and the fourth coil to outputs of the second coil and the fourth coil.

26. The radio frequency filter of claim 12, wherein the second via is the only via connecting the third coil to the fourth coil.
